(19) United States
(12) Patent Application Publication
(10) Pub. No.: US 2002/0012878 A1
(43) Pub. Date: Jan. 31, 2002

(54) PHOTOSENSITIVE COMPOSITION AND ITS USE FOR THERMALLY IMAGEABLE PRINTING PLATES

(76) Inventors: GERHARD HAUCK, BADENHAUSEN (DE); CELIN SAVARIAR-HAUCK, BADENHAUSEN (DE); HANS-JOACHIM TIMPE, OSTERODE/HARZ (DE)

Correspondence Address: BAKER & BOTTS, 30 ROCKEFELLER PLAZA, NEW YORK, NY, 10112

(21) Appl. No.: 09/429,531

(22) Filed: Oct. 28, 1999

(30) Foreign Application Priority Data
Oct. 30, 1998 (DE) 198 50 181.1

(51) Int. Cl. G03F 7/038

(52) U.S. Cl. 430/281.1; 430/286.1; 430/302; 430/287.1; 430/288.1

(57) ABSTRACT

The invention relates to photosensitive compositions containing an alkali-insoluble binder, which i.a. are excellently suitable for preparing thermally developable printing plates.

### BACKGROUND OF INVENTION

The invention relates to photosensitive compositions comprising a binder which is insoluble in aqueous-alkaline solutions having a pH value of ≦13.5 and which i.a. are excellently suitable for the preparation of thermally imageable printing plates.

Today the demands on photosensitive compositions which are particularly usable for high-capacity printing plates are quite high.

For improving the properties of photosensitive compositions and thus also the corresponding printing plates, basically two methods have been pursued. One of them relates to the improvement of the properties of the photosensitive components in the compositions (often negative diazo resins, photopolymers etc.), the other one to the detection of new polymeric compounds (“binders”), which are supposed to control the physical properties of the photosensitive layers. Particularly the latter method is of crucial importance for printing plates since the behavior in the developing and printing processes (such as developability, ink accepting capacity, scratch resistance, print run stability) is decisively influenced by the polymeric binders. Moreover, such polymeric compounds have a strong influence on the storage stability and photosensitivity of the materials.

In negative working printing plates, photosensitive compositions are used wherein after image-wise exposure, the exposed areas are cured. During the developing step, only the non-exposed areas are separated from the substrate. In positive working printing plates, on the other hand, photosensitive compositions are used, the exposed areas of which dissolve faster in a given developer than the non-exposed areas. This process is called photosolubilization. There are a great number of positive working photosensitive compositions having quinone diazides and phenolic resins as main components.

The latest developments in the field of printing plates deal with photosensitive compositions which can be imaged by lasers. In this type of imaging, films as intermediate information carrier may be omitted since lasers can be controlled by computers.

Plates which are imageable by IR lasers are known from EP-A-0 672 544, EP-A-0 672 954 and U.S. Pat. No. 5,491,046 and EP-A-0 819 985. These plates are negative working and require a preheating step after imaging whereby the image area of the layer, however, is cross-linked only to a minor extent. In order to comply with the highest print run demands and to exhibit sufficient resistance to pressroom chemicals, however, a further heating step—so-called baking—is required wherein these layers are further cross-linked. Another disadvantage of these negative working printing plates is that the image areas are generated by IR exposure, i.e. the curing of the layer depends on the laser exposure. Therefore, variations in the IR exposure such as its intensity directly affect the image areas. In positive working systems, this is not the case since the laser only “writes” the background (non-image area).

Regarding the photosensitive compositions of such positive systems, however, there is a certain dilemma. In order to obtain a high number of copies, cross-linked polymers would be required. However, such products are insoluble in the solvents or solvent mixtures usable for coating the plates so that one has to revert to non-cross-linked or only slightly cross-linked starting products. The required cross-linking is then obtained by preheating steps which can be carried out at different stages of the plate treatment.

A positive working system has recently been described in EP-A-0 819 980 where it is assumed that the non-image areas are formed by reacting the acid formed with carbon black. The image areas only form during a preheating step. Here, the same applies as above, i.e. the image areas have to be baked in order to obtain the highest possible number of copies.

Another positive working system is described in U.S. Pat. No. 5,658,708. The required cross-linking of the layer is already carried out during the drying step of the coating. For this, however, the system has to be treated for 10 minutes at 120° C. with chemical processes taking place which finally lead to cross-linking. However, the relatively long detention times at such high temperatures are an unacceptable expenditure of time in the common fully automatic plate production line. Here, baking does not lead to an increase in the number of copies since the cross-linking is partly reversed.

In spite of this intensive research in the field of photosensitive compositions for printing plates, all existing compositions call for improvement, particularly as regards their resistance to developer chemicals. Also, printing plates with known compositions often require a baking step for obtaining a high print run stability.

### SUMMARY OF THE INVENTION

Thus, it is the object of this invention to provide photosensitive compositions which allow the preparation of positive working printing plates having high print run stability and resistance to developer chemicals without requiring a baking step for obtaining these properties; moreover, the preparation of the positive working printing plates should be possible without an additional expenditure of time.

Another object of the invention is the use of such photosensitive compositions for preparing positive working printing plates.

### DETAILED DESCRIPTION OF THE INVENTION

These objects are achieved by a photosensitive composition comprising:

(i) a polymeric binder having both protective groups which (are cleavable by acid and heat treatment and functional groups which allow cross-linking with enol ethers, the binder being insoluble in aqueous-alkaline solvents having a pH value of ≦13.5,

(ii) at least one compound which releases acid upon heat treatment,

(iii) at least one radiation-absorbing compound which is capable of converting the absorbed radiation into heat and

(iv) one or several polyfunctional enol ethers capable of cross-linking.

An essential component of the photosensitive composition is the binder which is insoluble in aqueous-alkaline solvents having a pH value in the range of >7.0 to ≦13.5 and which is cross-linkable. These are linear organic polymers which can react with enol ethers in the presence of acid.

The preparation of such polymeric binders can be formally divided into two stages. In the first stage, addition polymers are prepared which contain acid groups or hydroxyl groups in the side chain. A great number of such polymers are sufficiently known to the person skilled in the art. Preferably they are copolymers of methacrylic acid, of acrylic acid, itaconic acid, crotonic acid, maleic acid or maleic acid half esters or vinylbenzoic acid with vinyl monomers such as olefins, wherein those having a hydroxyl group such as 2-hydroxyethylstyrene or 4-hydroxystyrene are particularly preferred, or of esters of the above-mentioned acids, particularly of such esters which still contain a hydroxyl group in the alcohol portion, such as for example hydroxyethyl acrylate or hydroxyethyl methacrylate. In such copolymers basically any combination of monomers and any ratio of the monomers relative to each other can be employed. The ratio of the acid group or hydroxyl group containing monomers to the other monomers is generally in the range of 3:97 to 80:20, particularly preferred is a ratio of 5:95 to 40:60.

Furthermore, in the first stage polymers can be prepared which contain a phenolic group. Particular examples of such polymers are novolaks such as phenol formaldehyde resins, m-cresol formaldehyde resins, p-cresol formaldehyde resins, or mixed m/p-cresol formaldehyde resins, or mixed phenol/cresol formaldehyde resins or polyhydroxy styrenes or copolymers from p-hydroxy styrene with esters of unsaturated acids such as for example methacrylic methyl esters or acrylic acid ethyl esters. Polymers or copolymers from hydroxy styrene may have been partly hydrated later on, as described for example in JP-A-01-103 604 and EP-A-0 401 499. Resols, prepared from the above-mentioned phenol or cresol formaldehyde combinations, can also be end products of the first stage as well.

All these polymers are soluble in aqueous-alkaline media having a pH value of ≦13.5.

In a formally second stage of the preparation of the binders according to the invention, parts of the carboxyl and hydroxyl groups are blocked by acid or heat cleavable groups. For this, all protective groups can be used which are mentioned in DE-A-44 148 96 or EP-A-0 762 206. Particularly preferred are tert.-butoxycarbonyl and tetrahydropyranyl protective groups. However, only such an amount of blockings may be effected that there are still enough carboxy and hydroxyl groups (aliphatic —OH or phenolic —OH) which can cross-link with enol ethers. The ratio of blocked groups and cross-linkable groups are generally at about 10:90 to 90:10, particularly preferred is a ratio between 30:70 and 70:30.

The thus modified polymeric binders are no longer soluble in aqueous-alkaline media having a pH value of >7.0 and ≦13.5. In general, they have a weight average molecular weight (M_{w}) between 1000 and 1000000, particularly preferred are polymers having molecular weights between 2000 and 100000.

Particularly preferred binders include polyvinyl phenol and partly hydrated polyvinyl phenol, the phenolic OH groups and/or optionally contained aliphatic OH groups of which are partially blocked by tetrahydropyranyl groups.

However, the polymeric binders usable in the composition according to the invention are not limited to the stated examples. They can be easily extended to other structurally analogous polymers by the person skilled in the art. The blocked polymeric binders can be present in the photosensitive compositions according to the invention preferably in an amount in the range of 1-95 weight %, more preferably between 20-90 weight %, particularly preferred between 30-60 weight %, based on the total composition.

The use of the polymers according to the invention which are insoluble in aqueous-alkaline solutions having a pH value of ≦13.5 instead of polymers which are also soluble in aqueous-alkaline solutions having a pH value of ≦13.5 surprisingly leads to a coating of the printing plate which is already sufficiently cross-linked at a drying time of 2 minutes at 100° C. and therefore has a higher resistance to developer chemicals after IR exposure, with the preheating (heat treatment after IR exposure but before developing) being less intensive. Another advantage is that the photosensitive compositions according to the invention can be formulated such that they exhibit a higher photosensitivity since fewer network binders have to be cleaved than in layers having a higher cross-linking degree, i.e. layers prepared from polymers without blockings.

Another important component of the composition according to the invention is the acid-former. It is a compound which releases acid upon heat treatment. Salts of onium cations such as diazonium, iodonium, sulphonium, phosphonium, ammonium, oxysulphoxonium and oxysulphonium and sulphoxonium salts with non-nucleophilic anions such as tetrafluoro borate, hexafluoro phosphate, hexafluoro arsenate, hexafluoro antimonate, trifluoromethanesulfonate, tetrakis(pentafluorophenyl)borat, pentafluoroethylsulfonate, p-methylbenzylsulfonate, ethylsulfonate, trifluoromethylacetate and pentafluoroethylacetate anions can be used. However, also C₁-C₅-alkylsulfonates, arylsulfonates, N-C₁-C₅-alkylsulfonylsulfoneamides, such as for example benzointosylat, 2-hydroxymethylbenzointosylate and N-methane sulfonyl-2,4-dimethylbenzenesulfonamide can be used. Finally, also combinations of onium salts and sulfonates or sulfone amides can be used as acid-formers. One or several acid-formers can be present in a composition according to the invention preferably in an amount in the range of 1-25 weight %, particularly preferred in the range of 5-20 weight %, based on the total composition. A preferred acid former is a diaryliodonium hexafluoroantimonate.

Another essential component of the compositions according to the invention is the radiation-absorbing compound which converts the absorbed radiation into heat. Preferably, these are pigments and/or dyes which absorb in the IR or near IR range. Such products are sufficiently known to the person skilled in the art. Preferably, they comprise dyes and/or pigments from the classes of triaryl methane, thiazolium, indolium, oxazolium, cyanine, polyaniline, polypyrrol and polythiophene dyes, or thiolene metal complexes, phthalocyanine complexes and carbon pigments. But also other black, yellow, orange, brown, red, violet, blue and green pigments as well as fluorescence pigments and pigments bound to polymers, such as azo, anthraquinone and quinacridone pigments can be used.

These pigments and/or dyes can be present in the photosensitive compositions according to the invention preferably in an amount in the range of 1-30 weight %, particularly preferred between 2-10 weight %, based on the total composition.

A preferred radiation-absorbing compound is 2-[2-[2-chloro-3-[2-(1,3-dihydro-1,1,3-trimethyl-2H-benzo[e]-indol-2-ylidene)-ethylidene]-1-cyclohexene-1-yl]-ethenyl]-1,1,3-trimethyl-1H-benzo[e]indolium-4-methylbenzolsulfonate.

Moreover, the photosensitive compositions according to the invention contain one or several enol ethers. These enol ethers have to have at least two enol ether groups in order to be able to effectively cross-link with the reactive groups of the polymeric binder. Enol ethers with only one enol ether group are not capable thereof. It is preferred that the boiling point of the enol ethers is not below 70° C. at normal atmospheric pressure, since otherwise the enol ethers might evaporate in the drying step of the plate, during which the cross-linking between the enol ether and the polymeric binder takes place at the same time, and thus they are no longer available for a cross-linking reaction.

A great number of polyfunctional enol ethers are known and commercially available which fulfill the above-mentioned requirements. Numerous examples are described e.g. in U.S. Pat. No. 5,658,708.

The amount of enol ethers in the compositions according to the invention is preferable between 1-80 weight %, preferably between 5-50 weight %, based on the total composition.

A preferred enol ether is bis [4-(ethenyloxy)butyl]-1,3-benzoldicarboxylic acid ester.

The exposure indicators usable in the photosensitive compositions according to the invention are known to the person skilled in the art. Exposure indicators from the series of triarylmethane dyes (such as Victoria blue BO, Victoria blue R, crystal violet) or azo dyes (such as 4-phenylazodiphenylamine, azobenzene or 4-N,N-dimethylaminoazobenzene). Preferably, the exposure indicators are present in the photosensitive composition in an amount of 0.02 to 10 weight %, particularly preferred are 0.5 to 6 weight %.

As dyes for increasing the image contrast such dyes are suitable which are easy to dissolve in the solvent or solvent mixture used for coating or which can be introduced as pigment in dispersed form. Suitable contrast dyes are i.a. rhodamine dyes, methyl violet, anthraquinone pigments and phthalocyanine dyes or pigments. Preferably, the dyes are present in the photosensitive composition in an amount of 1 to 15 weight %, particularly preferred are 2 to 7 weight %.

The photosensitive compositions according to the invention are preferably usable for the preparation of printing plates. Furthermore, they can also be used as radiation curable varnishes for surface protection as well as for the formulation of radiation curable printing inks in recording materials for preparing images on suitable substrates and receptor sheets, for preparing reliefs which can be used as printing forms, sieves and the like.

For the preparation of lithographic printing plates, aluminum as substrate is first grained by brushing in dry condition, by brushing with an abrasive suspension or by electrochemical brushing, for example in a hydrochloric acid electrolyte. The grained plates, which optionally have been subjected to an anodic oxidation in sulfur or phosphoric acid, are then subjected to a hydrophilizing aftertreatment, preferably in aqueous solutions of polyvinyl phosphonic acid or phosphoric acid. The details of the above-mentioned substrate pretreatment are well-known to the person skilled in the art.

The subsequently dried plates are coated with the photosensitive compositions prepared from organic solvents or solvent mixtures such that dry layer weights are obtained which are preferably in the range of 0.5 to 4 g/m², particularly preferred between 0.8 and 3 g/m².

The thus prepared printing plates are exposed and developed in the way known to the person skilled in the art. The developed plates are usually treated with a preserving agent (“gumming”). The preserving agents are aqueous solutions of hydrophilic polymers, wetting agents and further additives.

All references cited herein are incorporated by reference herein in their entirety. The invention will be explained in more detail on the basis of the following non-limiting examples.

### EXAMPLES

### Example 1

| | |
|---|---|
| 52 wt.-% | (with 50% protective groups blocked |
| PVP-S2 27062/34-3 | polyvinylphenol from the company BASF) |
| 15 wt.-% CD1012 | (photo acid generator of the |
| | diaryliodoniumhexafluoroantimonate type |
| | from Sartomer/Total) |
| 8 wt.-% ADS830A | (IR dye from American Dye Source) |
| 25 wt.-% Vectomer 4010 | (bisvinyl ether from Allied Signal) |

These components are dissolved under stirring in a mixture of

| | |
|---|---|
| 15 vol % Dowanol PM | (propylene-based glycol ether available from |
| | Dow) |
| 45 vol % methanol | |
| 40 vol % methylethylketone | |

After filtration of the solution, said solution was applied to an electrochemically grained and anodized aluminum foil, which had been aftertreated with polyvinyl phosphonic acid, by means of a wire-wound doctor and the layer was dried for 5 min at 100° C. The dry weight of the photocoating was about 2 g/m².

The thus prepared plate was then imaged in a trendsetter from the company Creo and then heated for 2 min at 100° C. The developing was carried out with a developer 9000 (developer from the company Kodak Polychrome Graphics) by pouring, spreading and abrading with plush after 20 sec of reacting.

Result:

The exposed areas were removed by the developer while the non-exposed areas remained, i.e. the plate worked positive. The 1% field of a 60 L/cm screen (UGRA/FOGRA Postscript Control Strip Version 1.1 EPS) was well reproduced.

The unexposed areas were cross-linked which became apparent in the excellent resistance to solvents; even after four minutes, still no attack by diacetone alcohol was observed.

The IR sensitivity was determined by means of a laboratory laser diode with the “exposing” being carried out at variable powers (current intensity varying between 500 and 1000 mA). The plate was clamped on a drum which rotated at constant speed by means of a motor. Also mechanically, the laser diode was moved by means of a spindle. Drum and spindle speed were selected such that a solid area was obtained. Then, the value from which the solid area (preheat and developing as described above) stopped accepting further ink after inking (ink 304 from the company Kodak Polychrome Graphics) was determined: 900 mA.

Instead of IR imaging, the plate can also be reproduced conventionally by UV light and a film as mask. Thus, under the same conditions as in the IR imaging, a free grey wedge grade of 3 (film: UGRA, exposure with 720 mJ/cm²) is obtained.

The resistance of the image areas to developer 9000 was very high. Even after 2 min, no attack could be observed.

The thus prepared plate was fitted into a sheet-fed offset printing machine and under normal printing conditions provided 100 000 copies of good quality. The plate could be further used for printing.

### Example 2

Example 1 was repeated, however, the substrate was aftertreated with phosphoric acid instead of polyvinyl phosphonic acid.

In this printing plate, too, a preheat temperature of 100° C. at 2 min was sufficient to obtain a free background.

When a preheat condition of 120° C. at 1 min was selected, the IR sensitivity was 800 mA.

In a conventional imaging by UV light, a grey wedge grade of 2 was obtained at 720 mJ/cm².

### Example 3

Example 1 was repeated, however, PVP-S2 of the company BASF with a hydrated portion of 40% was used.

The same results as in example 1 were obtained.

### Example 4

As in example 1, a 10% coating composition was prepared from the following components:

| | |
|---|---|
| 57 wt.-% | (with 50% protective groups blocked |
| PVP-S2 27062/34-3 | polyvinylphenol from the company BASF) |
| 10 wt.-% MS PF6 ® | (4-phenylamino-2-methoxybenzenediazonium |
| | salt, acid-former from the company Eastman |
| | Kodak) |
| 8 wt.-% Ec 2117 ® | (IR dye from the company FEW Chemicals) |
| 25 wt.-% Vectomer 4010 | (divinylether from the company Allied Signal) |

This solution was treated as in Example 1.

The IR sensitivity was also determined as in Example 1 and was 800 mA.

In this case, too, the resistance of the image areas to the developer 9000 was very high. Even after 2 min, no attack could been observed at the image areas.

### Comparative Example 1

A 10% coating composition was prepared from the following components:

| | |
|---|---|
| 37 wt.-% Carboset 526 ® | (unblocked acrylic acid polymer from the |
| | company Goodrich) |
| 10 wt.-% PD 140A ® | (unblocked novolak from the company |
| | Borden Chemical) |
| 15 wt.-% CD 1012 ® | (acid-former of the diaryliodoniumhexa- |
| | fluoroantimonate type from the company |
| | Sartomer/Total) |
| 8 wt.-% ADS 830A ® | (IR dye from the company American Dye |
| | Source) |
| 30 wt.-% Vectomer 4010 ® | (divinylether from the company Allied |
| | Signal) |

As solvent for these components, the same mixture as in Example 1 was used. The substrate was pretreated as described in Example 2. The drying time of the coating had to be extended to 6 minutes at 100° C. With shorter drying times, the layer is already considerably attacked after a reaction time of the developer 9000 (company Kodak Polychrome Graphics) of 1 min.

When the conditions of Example 1 are employed (2 min at 100° C.) layer residues still remain on the non-image area after IR radiation and reaction of the developer. In order to obtain a background-less plate, it has to be treated at a preheat temperature of 120° C. for 1½ min.

The IR sensitivity was then 1000 mA. After a reaction time of the developer 9000 of 2 min, however, a clear attack on the layer was observed. Already after 30 seconds, a clear attack on the layer by diacetone alcohol was observed.

A printing plate which was prepared with a usual reaction time of the developer of 40 s, was fitted in a sheet-fed offset printing machine and under normal conditions provided only 50 000 copies. Afterwards, the image areas on the plate were considerably worn out.

Conventional UV exposure with 720 mJ/cm² resulted in a grey wedge grade of 1.

### Comparative Example 2

Comparative Example 1 was repeated, however, the substrate was aftertreated as described in Example 1.

It turned out that there was no resistance to developer 9000; after a reaction time of 2 min, the image areas were removed completely.

A comparison of the experimental results shows that upon using the binder according to the invention, i.e. of a partly blocked polymer which is insoluble in aqueous-alkaline media having a pH value of ≦13.5 in the photosensitive composition, printing plates having high print run stability and showing excellent resistance to developers are obtained. Furthermore, for obtaining these properties, a lower temperature in the preheat step than in the use of binders, which are soluble in the above-mentioned alkaline media, is required.

We claim:

1. Photosensitive composition comprising
(i) a polymeric binder,
(ii) at least one compound which releases an acid upon heat treatment,
(iii) at least one radiation-absorbing compound capable of converting the absorbed radiation into heat, and
(iv) at least one cross-linkable polyfunctional enol ether,
wherein the polymeric binder has both protective groups which are cleavable by acid and heat treatment and functional groups which allow cross-linking with enol ethers, the binder being insoluble in aqueous-alkaline media having a pH value of =13.5.

2. Photosensitive composition according to claim 1, which additionally contains at least one exposure indicator.

3. Photosensitive composition according to claim 1 or 2, which additionally contains at least one dye for enhancing image contrast.

4. Photosensitive composition according to claim 1 the binder (i) being a polyvinyl phenol or partly hydrated polyvinyl phenol, the phenolic OH groups and/or optionally contained aliphatic OH groups of which are partly blocked by tetrahydropyranyl groups.

5. Photosensitive composition according to claim 1 with the compound which releases an acid upon heat treatment (ii) being a diaryliodonium hexafluoroantimonate.

6. Photosensitive composition according to claim 1, with the radiation-absorbing compound (iii) being 2-[2-[2-chloro-3-[2-(1,3-dihydro-1,1,3-trimethyl-2H-benzo[e]-indol-2-ylidene)-ethylidene]-1-cyclohexene-1-yl]-ethenyl]-1,1,3-trimethyl-1H-benzo[e]indolium-4-methylbenzolsulfonate.

7. Photosensitive composition according to claim 1 with the polyfunctional enol ether (iv) being bis[4-(ethenyloxy)butyl]-1,3-benzoldicarboxylic acid ester.

8. Photosensitive composition according to claim 1 with the polymeric binder (i) being present in an amount of 1 to 95 wt.-%, based on the composition.

9. Photosensitive composition according to claim 1 with the compound which releases an acid upon heat treatment (ii) being present in an amount of 1 to 25 wt.-% based on the composition.

10. Photosensitive composition according to claim 1 with the radiation-absorbing compound (iii) being present in an amount of 1 to 30 wt.-% based on the composition.

11. Photosensitive composition according to claim 1 with the polyfunctional enol ether (iv) being present in an amount of I to 80 wt.-% based on the composition.

12. Photosensitive composition according to claim 1 with the polyfunctional enol ether having a boiling point of 70° C. or more.

13. A method of preparing a printing plate comprising coating a substrate with the photosensitive composition of claim 1.

14. The method according to claim 13 wherein said substrate is pretreated sheet aluminum.
